(19) United States
(12) Patent Application Publication
(10) Pub. No.: US 2017/0248638 A1
(43) Pub. Date: Aug. 31, 2017

(54) TEST MEASUREMENT SYSTEM AND METHOD FOR USING SAME IN LOW VOLTAGE SYSTEMS

(71) Applicant: Engineering Systems Inc., Norcross, GA (US)

(72) Inventors: Massimo Mitolo, Irvine, CA (US); Thomas Joseph Bajzek, Naperville, IL (US)

(21) Appl. No.: 15/442,056

(22) Filed: Feb. 24, 2017

Related U.S. Application Data
(60) Provisional application No. 62/300,241, filed on Feb. 26, 2016.

(51) Int. Cl. G01R 19/165; G01R 31/327; G01R 31/04

(52) U.S. Cl. CPC G01R 19/16528; G01R 31/04; G01R 31/3277

(57) ABSTRACT

A test measurement system configured to be applied or otherwise coupled to an energized low-voltage receptacle or to live terminals of a feeder/branch circuit to detect the presence of potentially hazardous conditions. The test measurement system can be configured to indicate to a user if a ground-fault, which could occur at a load supplied by that energized low-voltage receptacle or live terminals of a feeder/branch circuit, would cause unsafe touch potentials to an individual.

### CROSS-REFERENCE TO RELATED APPLICATIONS

This application claims benefit of U.S. Provisional Application No. 62/300,241 filed Feb. 26, 2016, which application is herein specifically incorporated by reference herein in its entirety.

### BACKGROUND

Field of the Invention

This application relates generally to electrical testing and diagnostic equipment. More particularly, embodiments of the subject matter relate to a test measurement system for a feeder/branch circuit or outlet (receptacle).

Background Technology

Electrical receptacle testers generally are compact devices that are used to test the electrical connections of an alternating current (AC) power outlet. A typical outlet tester includes electrically conductive prongs that are arranged for compatibility with the socket layout of the outlet under test. A conventional outlet tester is simple to use; the device is coupled to an electrical outlet and indicator lights are illuminated in accordance with the electrical connections of the outlet. Most modern testers utilize three indicator lights, and the illumination pattern indicates whether the electrical outlet under test is wired correctly or whether there is a wiring fault.

Conventional AC outlet testers are typically unable to detect an incorrectly wired electrical outlet having a high resistance connection along the path of the equipment grounding conductor. Such a high resistance connection can occur due to improper installation of the equipment grounding conductor or due to deterioration of the electrical system. Problematically, conventional AC outlet testers also typically fail to detect incorrectly wired electrical outlets such as, for example, an electrical outlet having a jumper installed between the ground terminal and the neutral terminal or an electrical outlet in which the phase and neutral connections are reversed and a jumper exists between the ground terminal and the neutral terminal. Under these exemplary potentially hazardous conditions, conventional AC outlet testers typically indicate that the outlet is properly wired.

Thus, with respect to shock hazards, conventional AC outlet testers can fail to adequately warn users of potential risks. The determination of both magnitude and duration of touch voltage is of paramount importance to protect personnel against electric shock hazards, such as those caused by basic insulation failure in equipment/appliances or direct contact with live parts. In the United States, Table 250.122 of the National Electric Code (NEC) provides minimum sizes for equipment grounding conductors. However the NEC further indicates that: “[w]here necessary to comply with 250.4(A)(5) or (B)(4), the equipment grounding conductor shall be sized larger than given in this table.” This note indicates that excessive impedance of the equipment grounding conductor, also referred to as Protective Conductor (PE), for instance due to its length, may cause dangerous touch voltages during ground-fault conditions even if in compliance with the aforementioned table.

Accordingly, it would be beneficial to have a feeder/branch circuit or outlet (receptacle) tester that does not suffer from the shortcomings and deficiencies of conventional electrical outlet testers. It is desirable to have a feeder/branch circuit or (receptacle) tester that is configured to determine the magnitude of a voltage that is present in the tested low-voltage system. It is also desirable to have a feeder/branch circuit or outlet (receptacle) tester that is configurable be coupled to an energized low-voltage receptacle or live terminals of equipment and to indicate if a ground-fault occurring at a load supplied by that receptacle or terminals would cause unsafe touch potentials, as defined in IEEE and IEC standards. Furthermore, other desirable features and characteristics will become apparent from the subsequent detailed description and the appended claims, taken in conjunction with the accompanying drawings and the foregoing technical field and background.

### SUMMARY

Described herein is a test measurement system and a method of measuring the effectiveness of the equipment grounding conductor to ensure safety during electrical faults. In one aspect, the test measurement system can be configured to be applied or otherwise coupled to an energized low-voltage receptacle or to live terminals of a feeder/branch circuit. In a further aspect, the test measurement system can indicate to a user if a ground-fault occurring at a load supplied by that energized low-voltage receptacle or live terminals would cause unsafe touch potentials to an individual, as defined in IEEE and IEC standards. In one aspect, electrically unqualified personnel can have the ability to apply the test measurement system to conventional electrical outlets or receptacles, utilizing conventional standard plugs.

In one aspect, the test measurement system can be configured to determine at least one of: a) the magnitude of a fault-loop resistance; b) the fault current which would occur as a result of live parts contacting the equipment grounding conductor at the outlet or terminals; and/or c) the touch potential which would occur as a result of basic insulation failure within a piece of equipment. In one further aspect, the test measurement system can be configured to display the results of the above described parameters, namely to display at least one of the fault-loop resistance, fault current, and/or touch potential.

Various implementations described in the present disclosure can include additional systems, methods, features, and advantages, which can not necessarily be expressly disclosed herein but will be apparent to one of ordinary skill in the art upon examination of the following detailed description and accompanying drawings. It is intended that all such systems, methods, features, and advantages be included within the present disclosure and protected by the accompanying claims.

### BRIEF DESCRIPTION OF THE DRAWINGS

The features and components of the following figures are illustrated to emphasize the general principles of the present disclosure. Corresponding features and components throughout the figures can be designated by matching reference characters for the sake of consistency and clarity.

FIG. 1 is a functional block diagram of a test measurement system configured to be applied or otherwise coupled to an energized low-voltage receptacle or to live terminals of a feeder/branch circuit.

FIG. 2 is a flowchart describing an exemplary logic flow that can be implemented by the processor of the test measurement system of FIG. 1 to determine application applicability of the test measurement system.

FIG. 3 is a schematic view of an exemplary test circuit of the test measurement system showing a switch open so that a load resistance is not connected in the test circuit.

FIG. 4 is a flowchart describing an exemplary logic flow that can be implemented by the processor of the test circuit of the test measurement system shown in FIG. 3 to determine if an energized low-voltage receptacle or live terminals are properly energized within a predetermined range.

FIG. 5 is a schematic view of an exemplary test circuit of the test measurement system showing a switch open so that a load resistance is not connected in the test circuit and a capacitive voltage sensor forming a portion of the test circuit.

FIG. 6 is a flowchart describing an exemplary logic flow that can be implemented by the processor of the test circuit of the test measurement system shown in FIG. 5 to determine if a low-voltage receptacle or live terminals are properly energized within a predetermined range, and if the low-voltage receptacle or live terminals are properly wired.

FIG. 7 is a schematic view of an exemplary test circuit of the test measurement system with a switch closed so that a load resistance can be selectively connected in the test circuit.

FIG. 8 is a flowchart describing an exemplary logic flow that can be implemented by the processor of the test circuit of the test measurement system shown in FIG. 7 to determine if an equipment grounding conductor is present and/or determine if a ground fault circuit interrupter (GFCI) and/or a ground fault protector (GFP) is present.

FIG. 9 is a schematic view of an exemplary test circuit of the test measurement system with a switch open so that a load resistance is not connected in the test circuit.

FIG. 10 is a flowchart describing an exemplary logic flow that can be implemented by the processor of the test circuit of the test measurement system shown in FIG. 9 to determine a fault-loop resistance and/or a fault-loop current.

FIG. 11 is a schematic view of an exemplary test circuit of the test measurement system with a switch closed so that a load resistance is connected in the test circuit.

FIG. 12 is a flowchart describing an exemplary logic flow that can be implemented by the processor of the test circuit of the test measurement system shown in FIG. 11 to determine the prospective touch voltage of the tested energized low-voltage receptacle or live terminals.

### DETAILED DESCRIPTION

The present invention can be understood more readily by reference to the following detailed description, examples, drawings, and claims, and their previous and following description. However, before the present devices, systems, and/or methods are disclosed and described, it is to be understood that this invention is not limited to the specific devices, systems, and/or methods disclosed unless otherwise specified, and, as such, can, of course, vary. It is also to be understood that the terminology used herein is for the purpose of describing particular aspects only and is not intended to be limiting.

The following description of the invention is provided as an enabling teaching of the invention in its best, currently known embodiment. To this end, those skilled in the relevant art will recognize and appreciate that many changes can be made to the various aspects of the invention described herein, while still obtaining the beneficial results of the present invention. It will also be apparent that some of the desired benefits of the present invention can be obtained by selecting some of the features of the present invention without utilizing other features. Accordingly, those who work in the art will recognize that many modifications and adaptations to the present invention are possible and can even be desirable in certain circumstances and are a part of the present invention. It will also be apparent that the various aspects of the invention described herein may be added to other existing measurement devices/systems as an embodiment of the present invention. Thus, the following description is provided as illustrative of the principles of the present invention and not in limitation thereof.

As used throughout, the singular forms “a,” “an” and “the” include plural referents unless the context clearly dictates otherwise. Thus, for example, reference to “a resistor” can include two or more such resistors unless the context indicates otherwise.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “optional” or “optionally” mean that the subsequently described event or circumstance can or cannot occur, and that the description includes instances where said event or circumstance occurs and instances where it does not.

The word “or” as used herein means any one member of a particular list and also includes any combination of members of that list. Further, one should note that conditional language, such as, among others, “can,” “could,” “might,” or “can,” unless specifically stated otherwise, or otherwise understood within the context as used, is generally intended to convey that certain aspects include, while other aspects do not include, certain features, elements and/or steps. Thus, such conditional language is not generally intended to imply that features, elements and/or steps are in any way required for one or more particular aspects or that one or more particular aspects necessarily include logic for deciding, with or without user input or prompting, whether these features, elements and/or steps are included or are to be performed in any particular embodiment.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods.

The present methods and systems may be understood more readily by reference to the following detailed description of preferred embodiments and the Examples included therein and to the Figures and their previous and following description.

Unless specifically stated otherwise, and as may be apparent from the following description and claims, it should be appreciated that throughout the specification descriptions utilizing terms such as “processing,” “computing, calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices. In a similar manner, the term “processor” may refer to any device or portion of a device that processes electronic data from registers and/or memory to transform that electronic data into other electronic data that may be stored in registers and/or memory. A “computing platform” may comprise one or more processors

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described below with reference to block diagrams and flowchart illustrations of methods, systems, and apparatuses. It will be understood that each block of the block diagrams and flowchart illustrations, and combinations of blocks in the block diagrams and flowchart illustrations, respectively, can be implemented by computer program instructions. These computer program instructions may be loaded onto a general purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions.

It is contemplated that the processor or computer of the present application can operate in a networked environment using logical connections to one or more remote computing devices. By way of example, a remote computing device can be a personal computer, portable computer, a server, a router, a network computer, a peer device or other common network node, and so on. Logical connections between the processor or computer and a remote computing device can be made via a local area network and a general wide area network. Such network connections can be through a network adapter. It is further contemplated that such a network adapter can be implemented in both wired and wireless environments, which are conventional and commonplace in offices, enterprise-wide computer networks, intranets, and the Internet.

It is recognized that programs and components reside at various times in different storage components of the computing device, and are executed by the data processor(s) of the computer. Any of the disclosed methods can be performed by computer readable instructions embodied on computer readable media. Computer readable media can be any available media that can be accessed by a computer. By way of example and not meant to be limiting, computer readable media can comprise “computer storage media” and “communications media.” “Computer storage media” comprise volatile and non-volatile, removable and non-removable media implemented in any methods or technology for storage of information such as computer readable instructions, data structures, program modules, or other data. Exemplary computer storage media comprises, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computer.

The methods and systems can employ Artificial Intelligence techniques such as machine learning and iterative learning. Examples of such techniques include, but are not limited to, expert systems, case based reasoning, Bayesian networks, behavior based Al, neural networks, fuzzy systems, evolutionary computation (e.g., genetic algorithms), swarm intelligence (e.g., ant algorithms), and hybrid intelligent systems (e.g., expert inference rules generated through a neural network or production rules from statistical learning).

In one aspect, and referring to FIG. 1, disclosed herein is a test measurement system 10 and a method of determining the effectiveness of the equipment grounding conductor in a selectively coupled electrical system. In one aspect, the test measurement system 10 that can be configured to be applied or otherwise coupled to an energized low-voltage receptacle or to live terminals of a feeder/branch circuit. In a further aspect, the test measurement system 10 can comprise a housing 2 and a processor 4 that can be configured or otherwise programmed to indicate to a user if a ground-fault or basic insulation failure within connected equipment, which could occur at a load supplied by that energized low-voltage receptacle or live terminals of the feeder/branch circuit, would cause unsafe touch potentials to an individual, as defined in IEEE and IEC standards. Optionally, the test measurement system 10 can comprise a display 6 that is operably coupled to the processor 4 to display codes and/or messages to an operator with respect to various optional test results. In one aspect, the test measurement system 10 can be selectively connected to energized low-voltage receptacle or to live terminals or, optionally, the test measurement system 10 can be permanently mounted to existing installations to allow for continuous monitoring of desired touch voltages, which, as one skilled in the art will appreciate, can vary in time due to the aging of the existing installation electrical system. It is also contemplated that the results or measurements, displays, and/or alerts can be displayed on the display 6 of the test measurement system 10 or remotely, as desired.

In one aspect, it is contemplated that the test measurement system 10 can be configured so that electrically unqualified personnel can have the ability to apply the system to conventional electrical outlets or receptacles, utilizing conventional standard plugs.

In various aspects, as described in more detail below, the processor 4 of the test measurement system 10 can be configured or otherwise programmed to determine at least one of: a) the magnitude of a fault-loop resistance; b) the fault current which would occur as a result of live parts contacting the equipment grounding conductor at the outlet or terminals; and/or c) the touch potential which would occur as a result of basic insulation failure within a piece of equipment. In this aspect, the touch potential can be determined for the grounded enclosure of the equipment as connected to the receptacle or terminals being tested.

In one further aspect, the processor 4 of the test measurement system 10 can be configured or otherwise programmed to display the results of the above described parameters, namely to display at least one of the adjusted fault-loop resistance, fault current, and/or touch potential. Optionally, in a further aspect, the processor 4 of the test measurement system 10 can be configured or otherwise programmed to display a code for “Equipment Grounding Conductor Not Present” in Step 148 if an associated measured current value is zero. In this case, and as noted in Step 150 below, the measuring equipment shall not perform any further measurement. In yet another display aspect, it is contemplated that processor 4 of the test measurement system 10 can be configured or otherwise programmed to display a code for “Check for GFCI/GFP” if, in Step 158, the voltage at the outlet or terminals is below a predetermined value. In yet another display aspect, it is contemplated that processor 4 of the test measurement system 10 can be configured or otherwise programmed to display a code for “False Ground” in Step 136 to indicate the presence of a jumper between the ground screw and the neutral screw within the outlet, if, in step 134, the voltage between neutral conductor and equipment grounding conductor is below a predetermined value.

In yet another optional display aspect, it is contemplated that processor 4 of the test measurement system 10 can be configured or otherwise programmed to display a code for “Reverse Polarity” to indicate an erroneous connection of the phase conductor to the neutral screw or of the neutral conductor to the phase screw (i.e., erroneously swapping the phase and neutral conductors) within the outlet. In this step, if a voltage V1, which is measured across the capacitor C when a selectable probe is connected to the phase conductor, is less than a voltage V2, which is measured across the capacitor when the selectable probe is connected to the neutral conductor, the “Reverse Polarity” code will be displayed in Step 127.

In one aspect, with respect to determining the magnitude of a fault-loop resistance, one skilled in the art will appreciate that the fault-loop resistance Rₗₒₒₚ can be defined as the resistance of the loop composed of a supplying transformer winding (e.g., utility pole transformer), a supplying phase cable, and an equipment grounding conductor to the point of measurement. In a further aspect, it is contemplated that the test measurement system 10 can be configured or otherwise programmed to compare the fault current to the rating of the overcurrent protective device to determine the clearing time based on its trip curve.

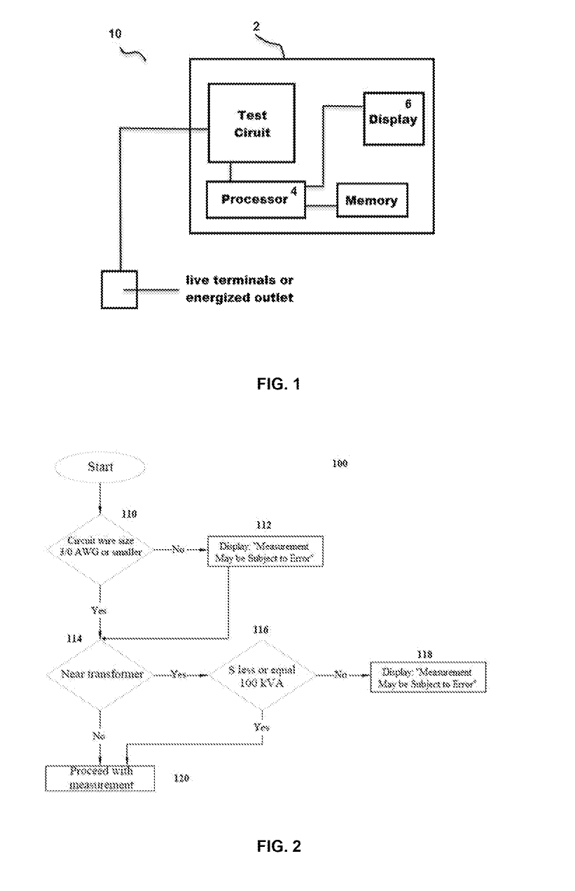

In one aspect, FIG. 2 illustrates a flowchart describing an exemplary logic flow that can be implemented by the processor 4 of the test measurement system of FIG. 1 to determine application applicability of the test measurement system. In this aspect, it is contemplated that the firmware running on the processor 4 will run an application routine 100 as depicted in FIG. 2. The application routine begins at Step 110 and runs a test on the size of the wire in the system being tested based on user input. If the wire size is greater than a predetermined wire size test criteria at Step 110, the application routine at Step 112 displays a code for “Measurement may be Subject to Error” before the application routine subsequently moves to Step 114 or optionally terminates. In one exemplary aspect, and not meant to be limiting, it is contemplated that the predetermined wire size test criteria comprises wire sizes that are about 3/0 AWG. If the wire size is less than or equal to the predetermined wire size test criteria at Step 110, the application routine 100 continues to Step 114 and performs the test on the proximity of the test measurement system to sourcing transformers with rated power levels.

In this aspect if, based on user input, the proximity or desired spacing of the measurement system from the sourcing transformers is less than a minimum distance in Step 114, then the application routine moves to Step 116, which notes the rated power of the sourcing transformers, which may be exemplarily imputed by the operator. In one exemplary aspect, and not meant to be limiting, the minimum distance of the test measurement system from the sourcing transformers with the predetermined rated power is greater than or equal to about 50 meters. If the test criteria of Step 114 are not met, i.e., the test measurement system is spaced a distance from the sourcing transformers that is greater than or equal to the minimum distance, the application routine 100 moves to Step 120 at which time the measurement routine 120 is initiated. If the test criteria of Step 114 are met, i.e., the test measurement system is spaced a distance from the sourcing transformers that is less than the minimum distance, the application routine moves to Step 116, in which the application routine 100 determines if the sourcing transformer has a rated power level that is less than or equal to a predetermined rated power. In one exemplary aspect, and not meant to be limiting, it is contemplated that the predetermined rated power comprises sourcing transformers with rated power that exceeds about 100 kVAR. If the rated power of the sourcing transformer, which is within the minimum proximity to the test measurement system 10, exceeds the predetermined rated power at Step 116, the application routine moves to Step 118 and the processor 4 of the test measurement system 10 can be configured or otherwise programmed to display a code for “Measurement may be Subject to Error” before the application routine subsequently moves to Step 120. If the rated power of the sourcing transformer, which is within the minimum proximity to the test measurement system 10, is less than or equal to the predetermined rated power at Step 116, the application routine proceeds to Step 120 at which time the measurement routine 120 is initiated.

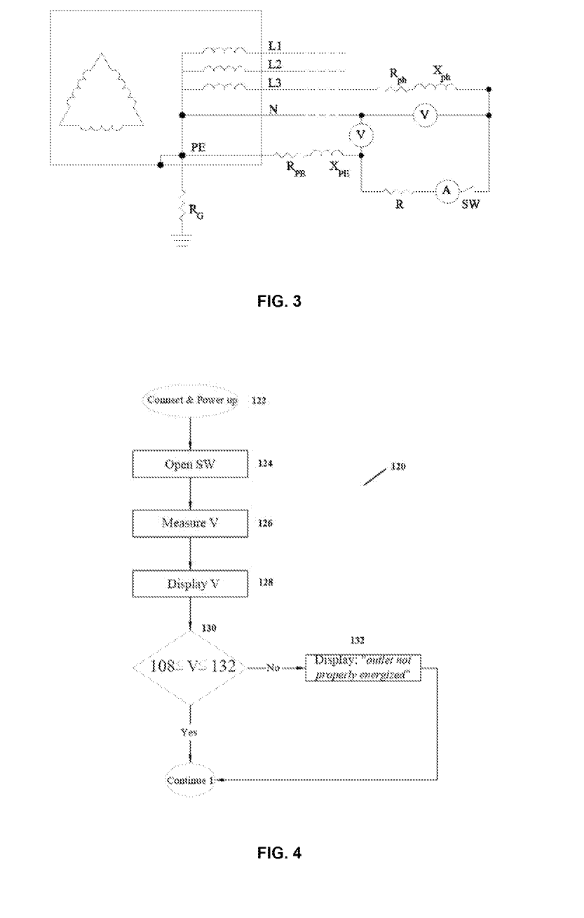

In one aspect, it is contemplated that the test measurement system 10 can determine if the low-voltage receptacle or the live terminals are properly energized. Referring to FIGS. 3 and 4, in Step 122, a test circuit of the test measurement system 10 is operably coupled to the low-voltage receptacle or the live terminals and is thereby energized. Subsequently, in Step 124, a switch SW of the test circuit is positioned in an open position such that a load resistance R is not connected in the test circuit. In Step 126, the test measurement system 10 measures the voltage V existing between the phase and neutral conductor of the test circuit and stores the measured voltage V value in the processor. In one aspect, it is contemplated that the test measurement system 10 measures the voltage V existing between the phase and neutral conductor in a predetermined time frame which can be a timeframe not exceeding one cycle, for example and not meant to be limiting, 17 ms at 60 Hz. Optionally, in Step 128, the measured voltage V value can be displayed to the operator. In Step 130, the measured voltage V value is compared to a predetermined range of acceptable voltages and, in Step 132, if the measured voltage V value does not fall within the predetermined range of acceptable voltages, the processor 4 of the test measurement system 10 can be configured or otherwise programmed to display a code for “Outlet Not Properly Energized”. In one exemplary aspect, and not meant to be limiting, the predetermined range of acceptable voltages can comprise voltages between about 100 to about 140 volts, preferably between about 105 to about 135 volts, and most preferably about 108 to about 132 volts. In a further aspect, after displaying the code for “Outlet Not Properly Energized” in Step 132 or if the measured voltage V value falls within the predetermined range of acceptable voltages in Step 130, the measurement routine continues to Step 140.

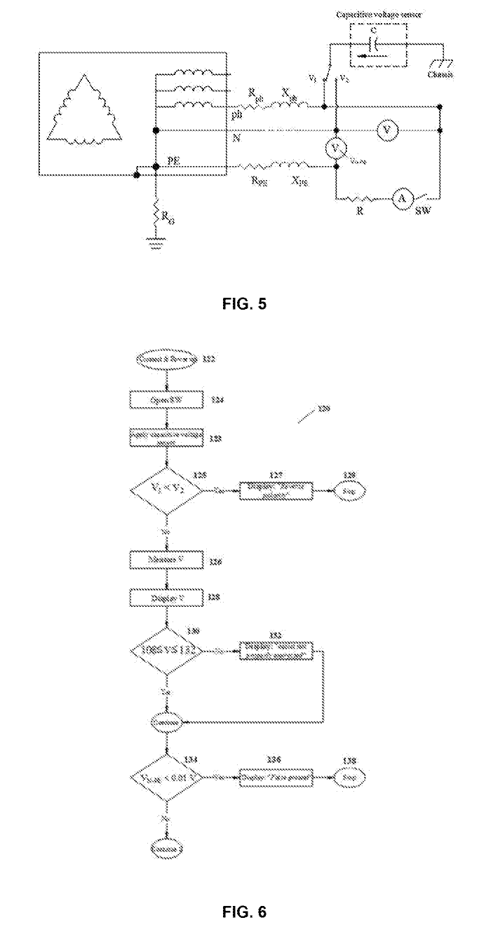

In an optional aspect, and as shown in FIGS. 5 and 6, the test circuit shown in FIG. 3 can further comprise a capacitive sensor C and a selectable probe that is configured to be selectably coupled to one of a phase conductor or a neutral conductor of the outlet being tested. In this exemplary aspect, in Step 122, the test circuit of the test measurement system 10 is operably coupled to the low-voltage receptacle or the live terminals and is thereby energized. Subsequently, in Step 124, a switch of the test circuit is positioned in an open position such that a load resistance is not connected in the test circuit. In Step 123, the capacitive voltages are sequentially measured by measuring a voltage V1 across the capacitor C when the selectable probe is connected to the phase conductor and measuring a voltage V2 across the capacitor when the selectable probe is connected to the neutral conductor. Subsequently, in Step 125, the determined capacitive voltages V1 and V2 are compared and, if V1 is less than V2, the processor 4 of the test measurement system 10 can be configured or otherwise programmed in Step 127 to display a code for “Reverse Polarity” to indicate an erroneous connection of the phase conductor to the neutral screw or of the neutral conductor to the phase screw (i.e., erroneously swapping the phase and neutral conductors) within the outlet and, as noted in Step 129, the measurement routine can be subsequently terminated. If however, it is determined in Step 125 that V1 is greater than or equal to V2, the measurement routine moves to Step 126 and the test measurement system 10 measures the voltage V existing between the phase and neutral conductor of the test circuit and stores the measured voltage V value in the processor. In one exemplary aspect, it is contemplated that the test measurement system 10 measures the voltage V existing between the phase and neutral conductor over a predetermined time frame which can be a timeframe not exceeding one cycle, for example and not meant to be limiting, 17 ms at 60 Hz. Optionally, in Step 128, the measured voltage V value can be displayed to the operator. In Step 130, the measured voltage V value is compared to a predetermined range of acceptable voltages and, in Step 132, if the measured voltage V value does not fall within the predetermined range of acceptable voltages, the processor 4 of the test measurement system 10 can be configured or otherwise programmed to display a code for “Outlet Not Properly Energized”. In one exemplary aspect, and not meant to be limiting, the predetermined range of acceptable voltages can comprise voltages between about 100 to about 140 volts, preferably between about 105 to about 135 volts, and most preferably about 108 to about 132 volts. In a further aspect, after displaying the code for “Outlet Not Properly Energized” in Step 132 or if the measured voltage V value falls within the predetermined range of acceptable voltages in Step 130, the measurement routine continues to Step 134.

In Step 134, the measured value of the voltage V between the neutral conductor and the equipment grounding conductor is compared to a predetermined value of acceptable voltage V_{N-PE}, and, in Step 180, if the measured voltage value V is less than the predetermined value of acceptable voltage V_{N-PE}, the processor 4 of the test measurement system 10 can be configured or otherwise programmed to display a code for “False Ground” and, as noted in Step 138, the measurement routine can be subsequently terminated. In one exemplary aspect, and not meant to be limiting, a predetermined range of acceptable voltages V_{N-PE} can comprise voltages between about 0.005 to about 0.015 volts, preferably between about 0.007 to about 0.013 volts, and most preferably about 0.01 volts. In a further aspect, if the measured voltage V_{N-PE} between the neutral conductor and the equipment grounding conductor is greater than or equal to the predetermined value of acceptable voltage in Step 134, the measurement routine continues to Step 140.

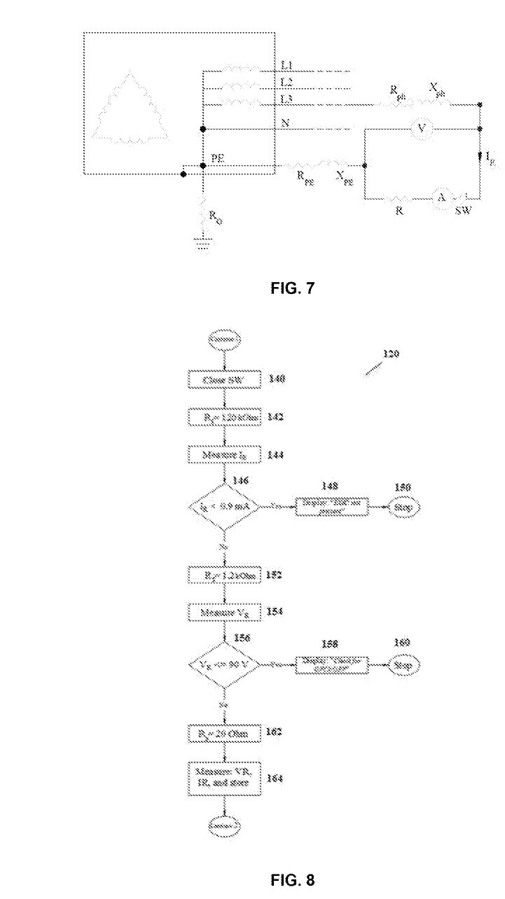

In another aspect, and referring now to FIGS. 7 and 8, in Step 140, the switch SW of the test circuit is positioned in a closed position such that a first load resistance R₁ is connected in the test circuit. As shown in Step 142, for example and not meant to be limiting, the first load resistance R₁ can be between about 100 to about 140 kΩ, preferably between about 110 to about 130 kΩ, and most preferably about 120 kΩ. In Step 144, the measurement routine measures a current I_{R} in the test circuit and then stores the measured current I_{R} value in the processor for comparison, in Step 146, to a predetermined minimum value of acceptable current. In one aspect, for example and not meant to be limiting, the predetermined value of minimum acceptable current can be between about 0.7 to about 1.1 mA, preferably between about 0.8 to about 1.0 mA, and most preferably about 0.9 mA. As shown in Step 148, if the measured I_{R} value is less than the predetermined value of minimum acceptable current, the processor 4 of the test measurement system 10 can be configured or otherwise programmed to display a code for “Equipment Grounding Conductor Not Present” and, as noted in Step 150, the measurement routine can be terminated. If however, the measured I_{R} value is greater than or equal to the predetermined value of minimum acceptable current, the measurement proceeds to Step 152, in which a second load resistance R₂ replaces the first load resistance R₁ in the test circuit. In one aspect, it is contemplated that the second load resistance R₂ is less than the first load resistance R₁ and, for example and not meant to be limiting, the second load resistance R₂ can be between about 1.0 to about 1.4 kΩ, preferably between about 1.1 to about 1.3 kΩ, and most preferably about 1.2 kΩ. For ease in illustration, the respective first and second resistances are shown as R in the exemplary circuit schematic.

Subsequently, in Step 154, the voltage V (which is referred to as V_{R} when the switch is closed) is measured across the second load resistance R₂. As one skilled in the art will appreciate, in the exemplary test circuit, Rₚₕ and R_{PE} are negligible when compared with the resistance of the second load resistance R₂. At Step 156, the measurement routine initiates a pass/fail routine to determine if the measured voltage V_{R} meet a predetermined voltage test criteria. If the pass/fail routine 156 determines that the measured voltage V_{R} is less than or equal to the predetermined voltage test criteria, the measurement routine moves to Step 158 and the processor 4 of the test measurement system 10 can be configured or otherwise programmed to display a code for “Check for GFCI/GFP”, and subsequently moves to Step 160 at which time the measurement routine 120 terminates.

If the pass/fail routine 156 determines that the measured voltage V_{R} is greater than the predetermined voltage test criteria, the measurement routine moves to Step 162. In one aspect, for example and not meant to be limiting, the predetermined value of the predetermined voltage test criteria can be between about 80 to about 100 Volts, preferably between about 85 to about 95 Volts, and most preferably about 90 Volts.

Step 162, a third load resistance R₃ replaces the second load resistance R₂ in the test circuit. In one aspect, it is contemplated that the third load resistance R₃ is less than the second resistance R₂ and, for example and not meant to be limiting, the third load resistance R₃ can be between about 10 to about 30Ω, and most preferably about 20Ω. For ease in illustration, and without limitation, the respective first, second and third resistances are shown as R in the exemplary circuit schematic. Subsequently, in Step 164, the voltage V_{R} and the current I_{R} are measured across the third load resistance R₃ and the values of I_{R} and V_{R} are stored in the processor memory.

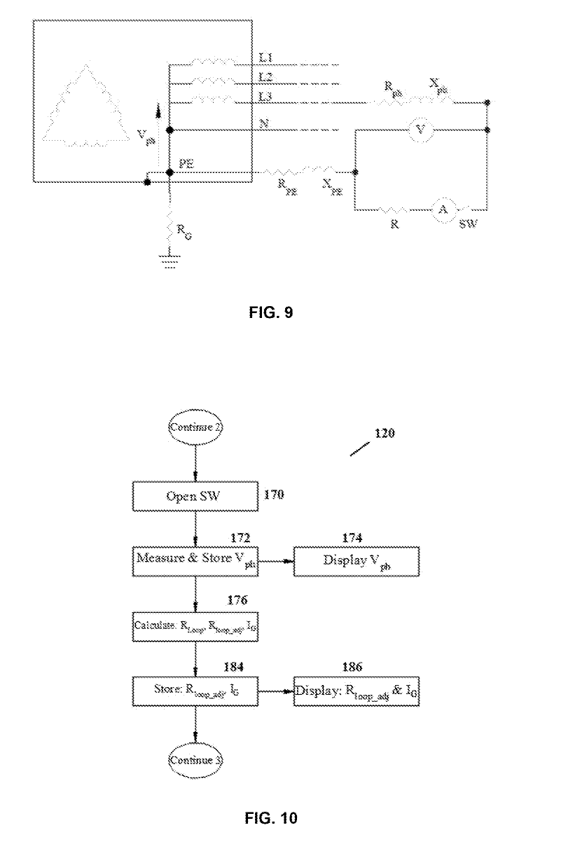

In one aspect, and referring now to FIGS. 9 and 10, the measurement routine 120 then continues and initiates a fault-loop routine. In this aspect, in Step 170, the switch of the test circuit is positioned in the open position and, in Step 172, measurement of a circuit voltage Vₚₕ is taken and stored in the processor memory. Optionally, in Step 174, the determined Vₚₕ can be displayed to an operator.

In a further aspect, in Step 176, the fault-loop routine can determine a fault-loop resistance value Rₗₒₒₚ, an adjusted fault-loop resistance value R_{loop-adj}, and a fault-loop current I_{G}. In this aspect, it is contemplated that the fault-loop routine can determine the fault-loop resistance value Rₗₒₒₚ by using the following equations:

Vₚₕ−I_{R}Rₗₒₒₚ−V_{R}=0; therefore

Rₗₒₒₚ=(Vₚₕ−V_{R})/I_{R}=((V_{PH}−V_{R})/V_{R})R.

Further, in determining the adjusted fault-loop resistance value R_{loop-adj}, the fault-loop routine can adjust the determined value of the fault-loop resistance value Rₗₒₒₚ to take into consideration of the relative increase in resistance in the test circuit as a result of the heat caused by the fault-loop current I_{G} passing through the circuit. In one aspect, it is contemplated that the adjusted fault-loop resistance value R_{loop-adj} can be determined by multiplying the determined fault-loop resistance value Rₗₒₒₚ value by a predetermined multiplication factor. In one aspect, it is contemplated that the predetermined multiplication factor, for example and not meant to be limiting, can be between about 1.2 to about 1.7, preferably between about 1.3 to about 1.6, and most preferably about 1.5. In a further aspect, it is contemplated that the fault-loop current I_{G} can be based on the determined adjusted fault-loop resistance value R_{loop-adj} by using the following equation:

I_{G}=Vₚₕ/R_{loop-adj}.

At Step 184 the processor 4 can store the determined values for R_{loop-adj} and I_{G}. Optionally, in Step 186, the processor 4 of the test measurement system 10 can be configured or otherwise programmed to display the R_{loop-adj} and I_{G} values to an operator.

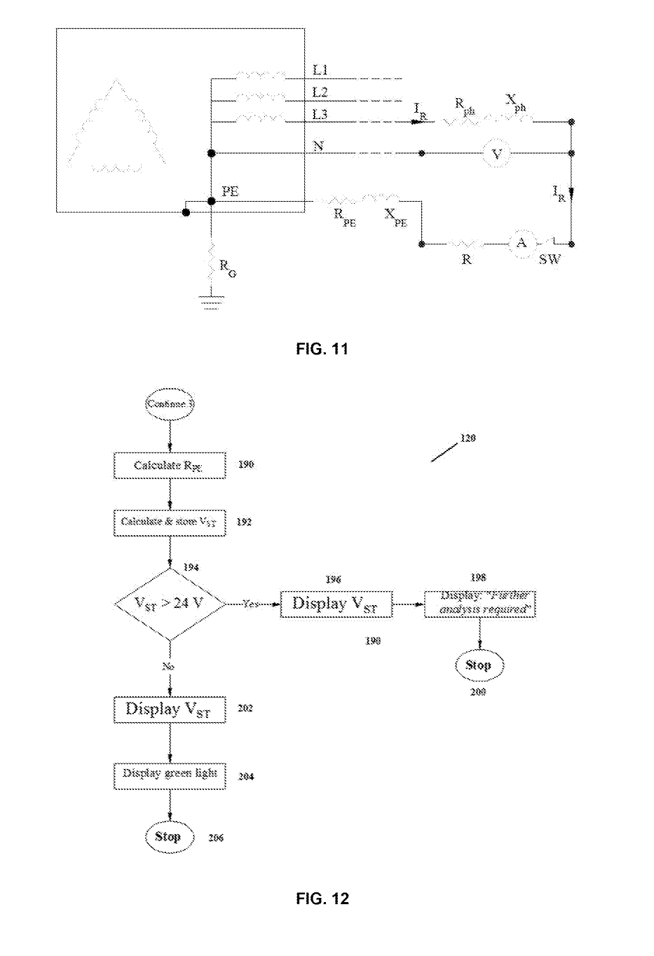

In another aspect, referring now to FIGS. 11 and 12, after storing the determined values in Step 184, the measurement routine 120 continues to Step 190, in which the measurement routine determines the resistance R_{PE} of the protective conductor. In this aspect, one skilled in the art will appreciate that:

V=V_{PH}−I_{R} Rₚₕ, where the current I_{R} is the current flowing through the third resistance R₃. Thus, to determine the resistance R_{PE} of the protective conductor, the following equations can be used:

V−I_{R}(R+R_{PE})=0; and therefore

R_{PE}=(V/I_{R})−R.

Subsequently, in Step 192, the processor 4 can determine and store a value for a prospective touch voltage V_{ST} of the operably coupled energized low-voltage receptacle or live terminals. In one aspect, the prospective touch voltage V_{ST} can be determined via the following exemplary equation:

V_{ST}=R_{PE}I_{G}.

At Step 194, the measurement routine initiates a pass/fail routine to determine if the measured voltage V_{ST} exceeds a predetermined voltage value. In this aspect, it is contemplated that the predetermined voltage value, for example and without limitation, can be between about 20 to about 28 Volts, preferably between about 22 to about 26 Volts, and most preferably about 24 Volts. If the pass/fail routine in Step 194 determines that the measured voltage V_{ST} is greater than or equal to the predetermined voltage value, the measurement routine moves to Step 196 and the processor 4 of the test measurement system 10 can be configured or otherwise programmed to display the determined value of the measured voltage V_{ST} and, optionally, in Step 198, the processor 4 of the test measurement system 10 can be configured or otherwise programmed to display a code for “Further Analysis is Required.” Subsequently, in Step 200, the measurement routine can terminate. If however the pass/fail routine in Step 194 determines that the measured voltage V_{ST} is less than the predetermined voltage value, the measurement routine moves to Step 202 and the processor 4 of the test measurement system 10 can be configured or otherwise programmed to display the determined value of the measured voltage V_{ST} and, optionally, in Step 204, the processor 4 of the test measurement system 10 can be configured or otherwise programmed to display a green light as a positive indication to the operator. Subsequently, in Step 206, the measurement routine terminates.

It should be emphasized that the above-described aspects are merely possible examples of implementations, merely set forth for a clear understanding of the principles of the present disclosure. Many variations and modifications can be made to the above-described embodiment(s) without departing substantially from the spirit and principles of the present disclosure. All such modifications and variations are intended to be included herein within the scope of the present disclosure, and all possible claims to individual aspects or combinations of elements or Steps are intended to be supported by the present disclosure. Moreover, although specific terms are employed herein, as well as in the claims which follow, they are used only in a generic and descriptive sense, and not for the purposes of limiting the described invention, nor the claims which follow.

That which is claimed is:

1. A test measurement system for an electrical system having an energized low-voltage receptacle or live terminals of a feeder/branch circuit; the test measurement system comprising:
a processor configured to determine if a ground-fault at a load supplied by the energized low-voltage receptacle or live terminals of the feeder/branch circuit would cause unsafe touch potentials to an individual, as defined in IEEE and IEC standards.

2. The test measurement system of claim 1, wherein the processor is further configured to determine/detect at least one of:
a magnitude of a fault-loop resistance;
a fault current which would occur as a result of live parts contacting the equipment grounding conductor at the energized low-voltage receptacle or live terminals of the feeder/branch circuit;
a touch potential which would occur as a result of basic insulation failure; and
the presence of potentially hazardous conditions including a jumper between the neutral and ground terminals and/or reverse polarity of the neutral and phase connections.

3. The test measurement system of claim 1, further comprising a housing.

4. The test measurement system of claim 1, wherein the test measurement system is selectively connected to the energized low-voltage receptacle or to live terminals of the feeder/branch circuit.

5. The test measurement system of claim 1, wherein the test measurement system is fixedly connected to existing electrical systems having an energized low-voltage receptacle or live terminals of the feeder/branch circuit to allow for continuous monitoring of desired touch voltages.

6. The test measurement system of claim 1, wherein the processor is configured to be applied to conventional electrical outlets or receptacles via a conforming standard plug.

7. The test measurement system of claim 2, wherein the touch potential is determined for a grounded enclosure of equipment that is connected to the energized low-voltage receptacle or live terminals of the feeder/branch circuit being tested.

8. The test measurement system of claim 2, wherein the processor is operably coupled to a display for displaying at least one of the fault-loop resistance, fault current, and touch potential.

9. The test measurement system of claim 8, wherein the processor is operably coupled to a display for the processor to display a code if an associated measured current value is zero.

10. The test measurement system of claim 8, wherein the processor is operably coupled to a display for the processor to display a code if the voltage at the energized low-voltage receptacle or live terminals of the feeder/branch circuit is below a predetermined value.

11. The test measurement system of claim 8, wherein the processor is operably coupled to a display for the processor to display a code if a the voltage between a neutral conductor and an equipment grounding conductor is below a predetermined value, which indicates the presence of a jumper between a ground screw and a neutral screw.

12. The test measurement system of claim 8, wherein the processor is operably coupled to a display for the processor to display a code to indicate an erroneous connection of a phase conductor to a neutral screw or of a neutral conductor to a phase screw.

13. The test measurement system of claim 1, wherein the processor is configured or otherwise programmed to compare the fault current to the rating of the overcurrent protective device to determine the clearing time.

14. A method for using a test measurement system for determining if a ground-fault exists that would cause unsafe touch potentials to an individual, as defined in IEEE and IEC standards, in an electrical system having an energized low-voltage receptacle or live terminals of a feeder/branch circuit, comprising:
determining if the low-voltage receptacle or the live terminals are properly energized;
measuring a current in the test circuit in which a first load resistance is selectively connected if the low-voltage receptacle or the live terminals are properly energized and then storing the measured current value for comparison to a predetermined minimum value of acceptable current;
replacing the first load resistance in the test circuit with a second load resistance and measuring a voltage across the second load resistance for comparison to a predetermined minimum value of acceptable voltage;
replacing the second load resistance in the test circuit with a third load resistance if the measured voltage across the second load resistance is greater than the predetermined voltage test criteria and measuring and storing a voltage and a current across the third load resistance;
running a fault-loop routine;
determining a resistance of the protective conductor of the electrical system;
determining and storing a value for a prospective touch voltage of the operably coupled energized low-voltage receptacle or live terminals; and
determining if the measured voltage exceeds a predetermined voltage value.

15. The method of claim 14, wherein the step of determining if the low-voltage receptacle or the live terminals are properly energized comprises:
energizing the test circuit of the test measurement system by operably coupled to the low-voltage receptacle or the live terminals;
positioning a switch of the test circuit in an open such that a load resistance is not connected in the test circuit;
measuring the voltage existing between a phase conductor and a neutral conductor of the test circuit and storing the measured voltage value; and
comparing the measured voltage value to a predetermined range of acceptable voltages.

16. The method of claim 14, wherein the step of determining if the low-voltage receptacle or the live terminals are properly energized comprises:
providing a test circuit of the test measurement system that comprises a capacitive sensor and a selectable probe that is configured to be selectably coupled to one of a phase conductor or a neutral conductor of the low-voltage receptacle or the live terminals;
energizing the test circuit of the test measurement system by operably coupled to the low-voltage receptacle or the live terminals;
positioning a switch of the test circuit in an open position such that a load resistance is not connected in the test circuit;
measuring a first voltage across the capacitor when the selectable probe is connected to the phase conductor and measuring a second voltage across the capacitor when the selectable probe is connected to the neutral conductor.
comparing the determined first and second voltages;
measuring the voltage existing between a phase conductor and a neutral conductor of the test circuit and storing the measured voltage value; and
comparing the measured voltage value to a predetermined range of acceptable voltages.

17. The method of claim 14, wherein the fault-loop routine comprises:
positioning a switch of the test circuit in an open position such that a load resistance is not connected in the test circuit;
measuring a circuit voltage taken and storing the measured circuit voltage;
determining a fault-loop resistance value Rₗₒₒₚ, an adjusted fault-loop resistance value R_{loop-adj}, and a fault-loop current I_{G}; and
storing the determined values for R_{loop-adj} and I_{G}.

18. The method of claim 17, wherein the fault-loop routine determines the fault-loop resistance value Rₗₒₒₚ by using equations:
Vₚₕ−I_{R}Rₗₒₒₚ−V_{R}=0; therefore
Rₗₒₒₚ=(Vₚₕ−V_{R})/I_{R}=((V_{PH}−V_{R})/V_{R})R.

19. The method of claim 17, wherein the fault-loop routine selectively adjusts the determined value of the fault-loop resistance value Rₗₒₒₚ to take into consideration the relative increase in resistance in the test circuit as a result of the heat caused by the fault-loop current I_{G} passing through the circuit.

20. The method of claim 19, wherein the adjusted fault-loop resistance value R_{loop-adj} can be determined by multiplying the determined fault-loop resistance value Rₗₒₒₚ value by a predetermined multiplication factor.

21. The method of claim 17, wherein the fault-loop routine determines the fault-loop current I_{G} by using equation:
I_{G}=Vₚₕ/R_{loop-adj}.

22. The method of claim 14, wherein the step of determining a resistance of the protective conductor of the electrical system is determined by using equation:
R_{PE}=(V/I_{R})−R.
where the current I_{R} is the current flowing through a third resistance load coupled to the test circuit.

23. The method of claim 22, wherein the prospective touch voltage can be determined via the equation:
V_{ST}=R_{PE}I_{G}.

24. The method of claim 14, further comprising, prior to the step of determining if the low-voltage receptacle or the live terminals are properly energized, testing the size of the wire in the electrical system and testing the proximity of the test measurement system to sourcing transformers with rated power levels if the wire size is less than or equal to a predetermined wire size.
